(19) United States
(12) Patent Application Publication
(10) Pub. No.: US 2010/0206715 A1
(43) Pub. Date: Aug. 19, 2010

(54) SPUTTERING APPARATUS, DOUBLE ROTARY SHUTTER UNIT, AND SPUTTERING METHOD

(75) Inventors: Taichi Hiromi, Minamitsuru-gun (JP); Tadaaki Murakami, Fujinomiya-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/704,743

(22) Filed: Feb. 12, 2010

(30) Foreign Application Priority Data
Feb. 16, 2009 (JP) 2009-033028
Feb. 8, 2010 (JP) 2010-025216

(51) Int. Cl. C23C 14/36

(52) U.S. Cl. 204/192.12; 204/298.11

(57) ABSTRACT

Two shutter plates form a double rotary shutter mechanism. A cylindrical second deposition shield is interposed between the first shutter plate disposed on the side of a target and the second shutter plate so as to surround a first opening formed in the first shutter plate. A cylindrical first deposition shield is interposed between a sputtering cathode and the first shutter plate so as to surround the front surface region of the target. This makes it possible to prevent a sputtering substance from passing through the gaps between the first shutter plate and the second shutter plate and between the first shutter plate and the sputtering cathode, and to, in turn, prevent generation of any cross-contamination.

### BACKGROUND OF THE INVENTION

1. Field of the Invention

The present invention relates to a sputtering apparatus having a structure useful for the manufacture of thin films, a sputtering method, and a double rotary shutter unit and, more particularly, to a sputtering apparatus including a plurality of targets, a double rotary shutter unit mounted in the sputtering apparatus, and a sputtering method.

2. Description of the Related Art

One known sputtering apparatus selects a target to be sputtered from a plurality of targets placed in a vacuum vessel using a double rotary shutter mechanism formed by combining two shutters independently controlled for rotation (see Japanese Patent Laid-Open No. 2005-256112).

The sputtering apparatus (multiple cathode sputtering deposition apparatus) described in Japanese Patent Laid-Open No. 2005-256112 includes four targets placed in a single vacuum vessel, and a double rotary shutter mechanism including two shutter plates which rotate independently of each other and include openings respectively formed in them. The double rotary shutter mechanism selects a target by combining the position of the opening formed in the first shutter plate and that of the opening formed in the second shutter plate, and continues discharge to the selected target. A film can be deposited on a substrate by a pre-sputtering process and a main sputtering process in the foregoing way.

This sputtering apparatus controls the rotational operation of the first shutter plate so that any substances contained in other targets never deposit on the target selected to be sputtered. This makes it possible to prevent any substances contained in other targets from adhering onto the surface of the selected target during pre-sputtering. This, in turn, makes it possible to prevent the occurrence of any cross-contamination during main sputtering.

Unfortunately, even the above-mentioned double rotary shutter mechanism may encounter cross-contamination, depending on the sputtering material and the discharge conditions. When, for example, gold (Au) prone to scatter to the periphery in large amounts is selected as the sputtering material, Au atoms may undesirably enter a tray holder and a sputtering cathode adjacent to the selected sputtering cathode and form films on them.

In addition, because the sputtering apparatus described in Japanese Patent Laid-Open No. 2005-256112 includes a sputtering gas inlet located at a position relatively far from the sputtering cathodes (targets), the pressure of the sputtering gas near the target is hard to rise during discharge triggering. This disadvantageously results in a difficulty in discharge or in stabilization of low-pressure discharge. This may also result in a difference in discharge pressure for each cathode position.

### SUMMARY OF THE INVENTION

The present invention has been made in consideration of the above-described problems, and provides a sputtering apparatus which can more reliably prevent any cross-contamination by preventing scattering of a sputtering substance to the periphery, a double rotary shutter unit mounted in the sputtering apparatus, and a sputtering method.

It is another object of the present invention to provide a sputtering apparatus which allows stable discharge and discharge triggering, a double rotary shutter unit mounted in the sputtering apparatus, and a sputtering method.

The inventors of the present invention repeated close studies in order to solve the above-described problems, and completed the present invention by acquiring new knowledge that it is possible to prevent any cross-contamination of a target and to stabilize the sputtering gas pressure by mounting deposition shields on shutter plates of the conventional double rotary shutter mechanism.

According to one aspect of the present invention, there is provided a sputtering apparatus comprising:

a plurality of sputtering cathodes placed in a vacuum vessel;

a double rotary shutter mechanism including a first shutter plate and a second shutter plate which are disposed to be independently rotatable while facing the sputtering cathode and each of which includes at least one opening formed therein at a predetermined position, the second shutter plate being located at a position farther from the sputtering cathodes than the first shutter plate; and

a first deposition shield which is interposed between the sputtering cathode and the first shutter plate and laterally surrounds a front surface region of the sputtering cathode on a side of the first shutter plate.

According to another aspect of the present invention, there is provided a double rotary shutter unit, comprising:

a first shutter plate and a second shutter plate which are disposed to be independently rotatable while facing a sputtering cathode placed in a vacuum vessel and each of which includes at least one opening formed therein at a predetermined position, the second shutter plate being located at a position farther from the sputtering cathodes than the first shutter plate,

wherein a second deposition shield which surrounds the opening in the first shutter plate is mounted on a surface of the first shutter plate on a side of the second shutter plate.

According to still another aspect of the present invention, there is provided a sputtering method performed by a sputtering apparatus which comprises a plurality of sputtering cathodes placed in a vacuum vessel, and a double rotary shutter mechanism including a first shutter plate and a second shutter plate which are disposed to be independently rotatable while facing the sputtering cathode and each of which includes at least one opening formed therein at a predetermined position, the second shutter plate being located at a position farther from the sputtering cathodes than the first shutter plate; in which a first deposition shield which laterally surrounds a front surface region of the sputtering cathode on a side of the first shutter plate is interposed between the sputtering cathode and the first shutter plate; and in which a second deposition shield which surrounds the opening in the first shutter plate is mounted on a surface of the first shutter plate on a side of the second shutter plate, the method comprising:

a pre-sputtering step of performing discharge while introducing a sputtering gas into the front surface region of the sputtering cathode on the side of the first shutter plate with an arrangement in which the opening in the first shutter plate is positioned in the front surface region and the opening in the second shutter plate is not positioned in the front surface region; and

a main sputtering step of performing discharge while introducing a sputtering gas into the front surface region of the sputtering cathode on the side of the first shutter plate with an arrangement in which both the opening in the first shutter plate and the opening in the second shutter plate are positioned in the front surface region.

According to the present invention, it is possible to narrow a gap through which a sputtering gas and a sputtering substance move from the plasma generation region on the front surface of a target. This, in turn, makes it possible to prevent scattering of a sputtering substance to the periphery during pre-sputtering and main sputtering, and thus to stabilize the pressure of the sputtering gas in the plasma generation region on the front surface of a target. It is therefore possible to provide a sputtering apparatus which prevents any cross-contamination between targets and has stable discharge performance and good ignitability, a double rotary shutter unit mounted in the sputtering apparatus, and a sputtering method.

Further features of the present invention will become apparent from the following description of exemplary embodiments with reference to the attached drawings.

### BRIEF DESCRIPTION OF THE DRAWINGS

FIG. 1 is a schematic sectional view of a sputtering apparatus;

FIG. 2 is an enlarged explanatory view of the periphery of a sputtering cathode; and

FIG. 3 is an enlarged perspective view of the periphery of the sputtering cathode.

### DESCRIPTION OF THE EMBODIMENTS

One embodiment of the present invention will be described below with reference to the accompanying drawings. Note that members and arrangements, for example, to be described hereinafter are merely examples which embody the present invention and do not limit the present invention, so they can be modified into various forms within the spirit and scope of the present invention, as a matter of course.

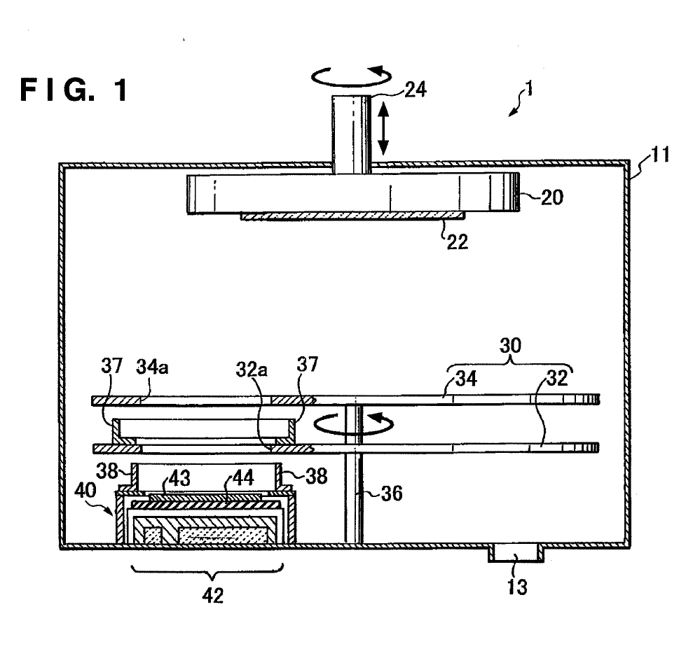

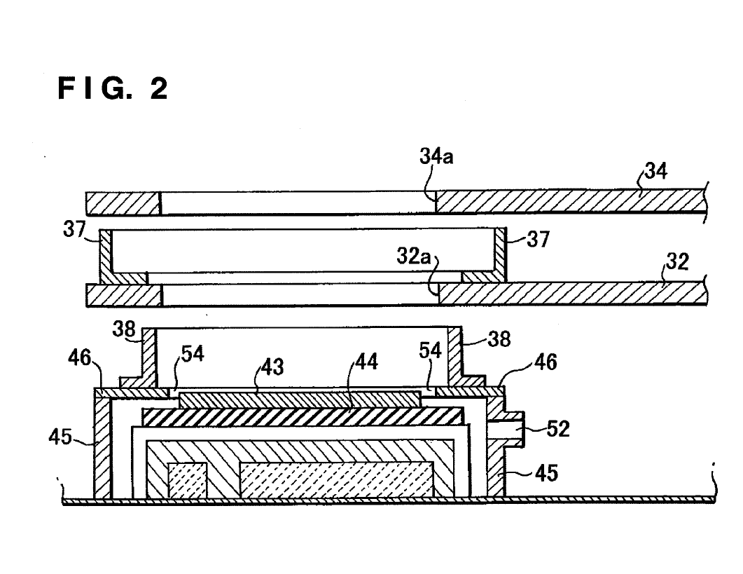

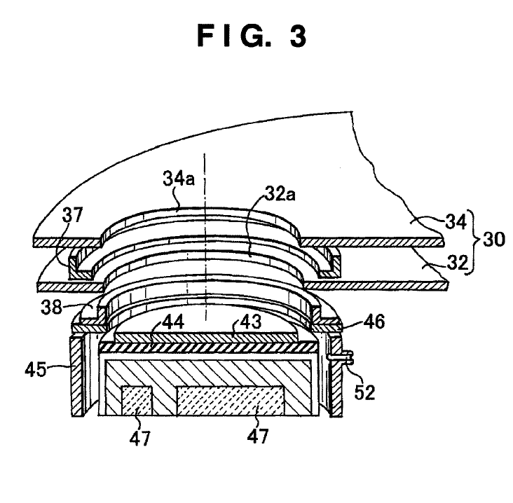

FIGS. 1 to 3 are views for explaining a sputtering apparatus (multiple cathode sputtering deposition apparatus) according to one embodiment of the present invention, in which FIG. 1 is a schematic sectional view of the sputtering apparatus; FIG. 2 is an enlarged explanatory view of the periphery of a sputtering cathode; and FIG. 3 is an enlarged perspective view of the periphery of the sputtering cathode. Note that some parts are not illustrated in the drawings for the sake of illustrative simplicity.

A sputtering apparatus 1 according to the present invention includes a plurality of targets made of different materials and a sputtering cathode in one sputtering deposition chamber (vacuum vessel), and forms a multilayer film by sequentially depositing films made of different materials on a substrate. The sputtering apparatus 1 can continuously deposit by sputtering a multilayer film, required to manufacture a magnetic head or MRAM including a GMR element or a TMR element, without intermitting the deposition from a lowermost layer to an uppermost layer on a substrate in one vacuum vessel, and therefore can efficiently deposit magnetic films on the substrate.

One embodiment of the sputtering apparatus 1 will be explained below. As shown in FIG. 1, the sputtering apparatus 1 according to this embodiment includes a vacuum vessel 11, substrate holder 20, double rotary shutter mechanism 30, sputtering means 40, and sputtering gas supply means (not shown) as main constituent elements. Although a substrate 22 is located on the upper side and the sputtering means 40 is located on the lower side in the sputtering apparatus 1 shown in FIG. 1, the present invention is also applicable to an arrangement in which the substrate 22 and the sputtering means 40 are interchanged between the upper and lower positions, as a matter of course.

The vacuum vessel 11 is made of stainless steel or an aluminum alloy typically used for known sputtering apparatuses, and is an airtight hollow body with a roughly rectangular parallelepiped shape. A load lock chamber (not shown) for loading/unloading the substrate 22 (substrate transport tray) is connected to the side surface of the vacuum vessel 11 via a gate valve (not shown).

An exhaust port 13 is formed in the vacuum vessel 11 near its bottom surface. The exhaust port 13 is connected to a vacuum pump such as a dry pump, a cryopump, or a turbo molecular pump, and can evacuate the vacuum vessel 11 to about 10⁻⁵ to 10⁻⁷ Pa.

The substrate holder 20 is a table-like member which can hold the substrate 22 on its lower surface, and can hold the substrate 22 using a chuck or a substrate transport tray (neither is shown). The substrate holder 20 is attached onto a substrate rotating shaft 24, which is supported in the upper portion of the vacuum vessel 11 to be controllable in its vertical movement and rotation while being maintained airtight. A known vertical level adjusting mechanism and rotation control mechanism can be used for the substrate rotating shaft 24, and a detailed description thereof will not be given.

The double rotary shutter mechanism 30 is interposed between the substrate holder 20 and the sputtering means 40. The double rotary shutter mechanism 30 has a structure in which two shutter plates which can be independently controlled for rotation through a rotating shaft are vertically stacked in parallel. The shutter plate disposed on the side of a sputtering cathode 42 (on the side of a target 43) is a first shutter plate 32, and the one disposed on the side of the substrate holder 20 (on the side of the substrate 22) is a second shutter plate 34. Note that “parallel” implies herein “virtually parallel”.

A rotating shaft 36 has a double structure including a pipe-like member (not shown) disposed on its outer side and a bar-like member (not shown) disposed on its inner side, both of which can be independently controlled for rotation. The pipe-like member is connected to the first shutter plate 32, and the bar-like member is connected to the second shutter plate 34. A known rotation control mechanism can be used for the rotating shaft 36, and a detailed description thereof will not be given.

The first shutter plate 32 and second shutter plate 34 include openings 32a and 34a formed in their predetermined portions. For example, the first shutter plate 32 includes an opening (first opening) 32a formed in it, and the second shutter plate 34 includes an opening (second opening) 34a formed in it. The respective openings (first opening 32a and second opening 34a) are formed to be alignable on at least one target, and have diameters equal to or slightly larger than that of the target. Note that the above-mentioned positions and numbers of openings 32a and 34a are merely examples, and the present invention is not limited to them.

The edges of the first opening 32a and second opening 34a are preferably tapered. The amount of adhesion of a sputtering substance onto the edge of the first opening 32a can be reduced by tapering this edge into a smooth curved shape. This makes it possible to prevent, e.g., any abnormal discharge and contamination attributed to a phenomenon in which the sputtering substance adhering on the edge of the first opening 32a peels off and falls onto the target 43.

The first shutter plate 32 preferably mounts a deposition shield (second deposition shield 37) so as to surround the formed first opening 32a.

The second deposition shield 37 has its lower portion bent inwards or outwards and naturally has a roughly L-shaped cross-section, and this lower portion is mounted on the first shutter plate 32. Although the height of the second deposition shield 37 may be arbitrary, it is set low enough not to bring the second deposition shield 37 into contact with the second shutter plate 34 and enough to suppress migration of the sputtering gas from the front surface region of the target 43. In this embodiment, the gap between the second deposition shield 37 and the second shutter plate 34 is adjusted to a minimum distance beyond which they interfere with shutter rotation.

The second deposition shield 37 is spaced apart from the edge of the first opening 32a by a predetermined distance. More specifically, the second deposition shield 37 has a diameter equal to that of the sputtering cathode 42 so as to avoid the adverse effect of a magnetic field generated by the sputtering cathode 42. The distance from the periphery (edge) of the first opening 32a to the inner portion of the second deposition shield 37 is determined in accordance with the diameter of the second deposition shield 37. An example of the adverse effect of a magnetic field generated by the sputtering cathode 42 is discharge instability.

On the other hand, the direct distance from the edge of the first opening 32a to the inner portion of the second deposition shield 37 is desirably set longer than the height of the second deposition shield 37. This distance setting can greatly decrease the possibility that the substance adhering on the second deposition shield 37 falls into the first opening 32a even when this substance peels off and partially hangs over the first opening 32a. That is, it is possible to prevent, e.g., any abnormal discharge and contamination attributed to a phenomenon in which the peeled substance adheres onto the target 43.

In this embodiment, the second deposition shield 37 is mounted on the first shutter plate 32 while satisfying all the above-mentioned conditions.

Although the same effect can be produced even when the distance from the edge of the first opening 32a to the inner portion of the second deposition shield 37 is set longer, this distance is desirably about twice or less the height of the second deposition shield 37. This is to prevent the second deposition shield 37 from coming into contact with an adjacent second deposition shield disposed around another opening of the first shutter plate. In this embodiment, the height of the second deposition shield 37 is 13 mm, whereas the distance from the edge of the first opening 32a to the inner portion of the second deposition shield 37 is 16 mm.

The sputtering means 40 includes a plurality of sputtering cathodes 42 set at predetermined positions on the bottom surface of the vacuum vessel 11, and targets 43 containing substances for use in sputtering deposition as main constituent elements. The targets 43 are fixed on backing plates 44 disposed on the upper surface of the sputtering cathodes 42.

In this embodiment, the sputtering means 40 includes four sputtering cathodes 42, above which targets 43 containing different sputtering substances are respectively disposed. The sputtering cathode 42 is a magnetron electrode including rotary magnets 47 disposed on the lower side of the backing plate 44.

As shown in FIG. 2, each sputtering cathode 42 has its side surface surrounded by a roughly circular cylindrical member 45, and its outer periphery, on the side of the backing plate 44, covered with a ring-shaped cathode shield 46. While the target 43 is attached on the sputtering cathode 42, the cathode shield 46 surrounds the outer periphery of the target 43 so as to have nearly the same surface level as the upper surface of the target 43. Each sputtering cathode 42 and each cylindrical member 45, and each sputtering cathode 42 and each cathode shield 46 have predetermined gaps formed between them. Although the cylindrical member 45 in this embodiment has a circular cylindrical shape, the present invention is not limited to this as long as the cylindrical member 45 has a shape which surrounds each sputtering cathode 42.

An embodiment of one arbitrary sputtering cathode 42 will be explained below. The cylindrical member 45 is a roughly circular cylindrical stainless steel member which covers the sputtering cathode 42 with a predetermined gap between them. The cylindrical member 45 has its upper end connected to the outer peripheral edge (outer edge) of the cathode shield 46, and its lower end fixed and held on the side surface of the sputtering cathode 42 or on the bottom surface of the vacuum vessel 11. The gap between the inner side surface of the cylindrical member 45 and the side surface of the sputtering cathode 42 is adjusted to a minimum distance beyond which they interfere with shutter rotation.

The lower end of the cylindrical member 45 is desirably fixed on the side surface of the sputtering cathode 42 or on the bottom surface of the vacuum vessel 11 throughout the entire circumference while being maintained airtight.

The cathode shield 46 is a roughly ring-shaped stainless steel member disposed parallel to the target 43, and surrounds the outer periphery of the target 43 with a predetermined gap between them. The outer peripheral edge (outer edge) of the cathode shield 46 is airtightly in contact with the upper end of the cylindrical member 45 throughout the entire circumference. Although the gap between the inner peripheral edge (inner edge) of the cathode shield 46 and the side surface of the target 43 can have an arbitrary distance between them, the cathode shield 46 is preferably spaced apart from the outer periphery of the target 43 by a predetermined distance throughout the entire circumference. Note that “parallel” mentioned above implies “virtually parallel” and “a predetermined distance” mentioned above implies “a virtually predetermined distance”.

As will be described later, both the gaps formed between the sputtering cathode 42 and the cylindrical member 45 and between the sputtering cathode 42 and the cathode shield 46 function as a sputtering gas introduction path and a gas outlet 54.

Although the cathode shield 46 is disposed nearly flush with the upper surface of the target 43, it can also be disposed slightly above the target 43 or disposed to cover the upper outer edge of the target 43.

The cathode shield 46 is characterized by including a first deposition shield 38 mounted on its upper surface (its surface on the side of the first shutter plate 32). The first deposition shield 38 is interposed between the cathode shield 46 and the first shutter plate 32. The first deposition shield 38 has its lower portion bent inwards or outwards and naturally has a roughly L-shaped cross-section, and this lower portion is mounted on the cathode shield 46. Although the height of the first deposition shield 38 may be arbitrary, it is set low enough not to bring the first deposition shield 38 into contact with the first shutter plate 32 and enough to suppress migration of the sputtering gas from the front surface region of the target 43.

The diameter of the first deposition shield 38 is desirably set equal to that of the first opening 32a formed in the first shutter plate 32. This is to minimize the area of a region where the sputtering substance adheres onto the first shutter plate 32.

The first deposition shield 38 mentioned above may be mounted on the lower surface of the first shutter plate 32. Further, a member corresponding to the first deposition shield 38 may be formed by extending the cylindrical member 45 toward the first shutter plate 32. In either case, it is possible to produce the same effect as in the above-mentioned arrangement in which the first deposition shield 38 is mounted on the upper surface of the cathode shield 46.

The sputtering gas supply means (not shown) includes at least a gas cylinder (not shown) serving as a sputtering gas supply source, a sputtering gas guide pipe (not shown), and the gas outlet 54. The pipe includes, e.g., a valve and flow controller (neither is shown). A sputtering gas supplied from the gas cylinder is guided into the vacuum vessel 11 through the pipe and is discharged from the gas outlet 54.

As shown in FIG. 2, the gas outlet 54 in this embodiment is formed as the above-mentioned gap between the target 43 and the cathode shield 46. Also, the pipe is connected to a gas inlet 52 which introduces a sputtering gas into the gap between the sputtering cathode 42 and the cylindrical member 45. That is, a sputtering gas is introduced from the gas inlet 52 into the gap between the sputtering cathode 42 and the cylindrical member 45 through the pipe, and is subsequently introduced from the gap (gas outlet 54) between the target 43 and the cathode shield 46 into the front surface region (plasma generation region) of the target 43.

By introducing a sputtering gas into the gap between the sputtering cathode 42 and the cylindrical member 45, the pressure of the gas supplied into the gap (gas outlet 54) between the target 43 and the cathode shield 46 can be stabilized. That is, it is possible to reduce a fluctuation in sputtering gas pressure and a difference in sputtering gas pressure attributed to the gas introduction position. One reason for this is that a gas is selectively introduced into discharge target portions. Another reason for this is that the gas efficiently circulates on a circular target because the gas outlet 54 has a ring shape.

The sputtering gas pressure can be stabilized by forming the gap between the sputtering cathode 42 and the cylindrical member 45 to be larger than that between the target 43 and the cathode shield 46. This is because a buffer action is enhanced upon temporarily storing the sputtering gas.

As has been described above, by introducing a sputtering gas onto the front surface of the target 43 through the gap (gas outlet 54) between the target 43 and the cathode shield 46, the sputtering gas can be uniformly supplied by ring-like circulation from the entire circumference of the outer edge of the target 43 into the front surface region of the target 43, and thus to stabilize the pressure of the sputtering gas in this region. Moreover, the first deposition shield 38 and second deposition shield 37 can regulate the amount of outflow of the sputtering gas from the front surface region of the target 43. This, in turn, makes it possible to set the pressure of the sputtering gas in the front surface region of the target 43 to be higher than that in the vacuum vessel 11 spaced apart from the target 43. It is therefore possible to provide a sputtering apparatus 1 with more stable discharge performance and discharge triggering (ignitability). The front surface region of the target 43 and the front surface region of the sputtering cathode 42 on the shutter plate side mean herein the plasma generation regions of the target 43 and sputtering cathode 42 on the side of the substrate 22.

A double rotary shutter unit (double rotary shutter mechanism 30) is preferably formed by unitizing in advance the first shutter plate 32 which mounts the second deposition shield 37 and the second shutter plate 34. This unitization can facilitate positioning of the first shutter plate 32 and second shutter plate 34 by adjustment of the amount of gap between them and other operations when they are assembled to the sputtering apparatus 1. That is, it is possible to improve both the maintenance performance and the assembly accuracy.

The operation and effect of the sputtering apparatus 1 according to this embodiment will be explained hereinafter.

First, pre-sputtering is performed while the position of the first opening 32a formed in the first shutter plate 32 is aligned with that of the target 43 for pre-sputtering and the position of the second opening 34a formed in the second shutter plate 34 is not aligned with that of the target 43. That is, the front surface region of the target 43 is surrounded by the first deposition shield 38, second deposition shield 37, and second shutter plate 34. Since a sputtering gas is introduced from the gas outlet 54 in the outer periphery of the target 43, the pressure of the sputtering gas in the front surface region of the target 43 readily rises and this facilitates ignition and discharge.

The first deposition shield 38 and second deposition shield 37 prevent the substance sputtered by this pre-sputtering from entering an adjacent target 43. This makes it possible to prevent any cross-contamination between targets 43. Note that the same position on the second shutter plate 34 is controlled to be located on the upper side of one target 43. That is, during pre-sputtering, respective predetermined regions on the second shutter plate 34 face corresponding targets 43. This is to prevent any contamination attributed to the fact that the substances contained in respective targets 43 adhere onto the lower surface of the second shutter plate 34 positioned on the upper side of the respective targets 43 during pre-sputtering.

Next, main sputtering is performed while the positions of both the first opening 32a formed in the first shutter plate 32 and the second opening 34a formed in the second shutter plate 34 are aligned with that of the target 43 for sputtering (main sputtering). That is, the front surface region of the target 43 is laterally surrounded by the first deposition shield 38 and second deposition shield 37 but is open to the substrate 22. Again, since a sputtering gas is introduced from the gas outlet 54 in the outer periphery of the target 43, the pressure of the sputtering gas in the front surface region of the target 43 readily rises and this facilitates ignition and discharge (especially low-pressure discharge).

Because the first deposition shield 38 and second deposition shield 37 prevent the substance sputtered by the main sputtering from entering an adjacent target 43 as well, no cross-contamination occurs between targets 43.

When a plurality of targets 43 are sputtered at once, the above-mentioned state can be set by changing the arrangements and numbers of openings formed in the first shutter plate 32 and second shutter plate 34.

As described above, the sputtering apparatus 1 according to this embodiment can narrow a gap through which a sputtering gas and a sputtering substance move from the plasma generation region on the front surface of the target 43 by at least one of the first deposition shield 38 and the second deposition shield 37 mounted on the cathode shield 46 and on the first shutter plate 32, respectively.

For this reason, it is possible to prevent the sputtering substances sputtered during pre-sputtering and main sputtering from scattering to the periphery, and thus to stabilize the pressure of the sputtering gas in the front surface region of the target 43. This, in turn, makes it possible to prevent any cross-contamination between targets 43 and obtain stable discharge and good ignitability even when a substance (e.g., Au) prone to scatter to the periphery in large amounts is sputtered.

Also, the sputtering gas pressure can be stabilized while uniformly supplying a sputtering gas into the front surface region of the target 43 by introducing the sputtering gas into this region through the gap between the outer periphery of the target 43 and the roughly ring-shaped cathode shield 46. Moreover, the pressure of the sputtering gas in the front surface region of the target 43 can be set higher than that in the vacuum vessel 11 spaced apart from the target 43. Especially because the gas supply port (gas outlet 54) lies close to the target 43, a high sputtering gas pressure can be obtained when a trigger requires a temporary high pressure. It is also possible to always obtain stable discharge over a wide range of sputtering gas pressures from high pressures to low pressures. This allows more stable discharge and better ignitability.

The sputtering apparatus 1 according to this embodiment includes the double rotary shutter mechanism 30 and therefore can attain both downsizing and cost reduction as compared with a structure (separate shutter structure) in which shutters are separately disposed on individual sputtering cathodes 43. This is because, unlike the separate shutter structure, the sputtering apparatus 1 need not be provided with clearances to let the shutter plates run off as the shutters open, and rotation introduction mechanisms for respective shutters.

Although both the first shutter plate and second shutter plate mount the deposition shields in this embodiment, the effect of the present invention can be satisfactorily obtained even when only the first shutter plate mounts the deposition shield.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-033028, filed Feb. 16, 2009, and Japanese Patent Application No. 2010-025216, filed Feb. 8, 2010, which are hereby incorporated by reference herein in their entirety.

What is claimed is:

1. A sputtering apparatus comprising:
a plurality of sputtering cathodes placed in a vacuum vessel;
a double rotary shutter mechanism including a first shutter plate and a second shutter plate which are disposed to be independently rotatable while facing said sputtering cathode and each of which includes at least one opening formed therein at a predetermined position, said second shutter plate being located at a position farther from said sputtering cathodes than said first shutter plate; and
a first deposition shield which is interposed between said sputtering cathode and said first shutter plate and laterally surrounds a front surface region of said sputtering cathode on a side of said first shutter plate.

2. The apparatus according to claim 1, wherein a second deposition shield which surrounds the opening in said first shutter plate is mounted on a surface of said first shutter plate on a side of said second shutter plate.

3. The apparatus according to claim 2, wherein said second deposition shield is configured to have a diameter equal to a diameter of said sputtering cathode.

4. The apparatus according to claim 1,
wherein said sputtering cathode comprises
a cathode shield which surrounds an outer periphery of a target with a predetermined gap therebetween, and a cylindrical member which is connected to said cathode shield and surrounds a side surface of said sputtering cathode with a predetermined gap therebetween, and
wherein a sputtering gas can be introduced onto a front surface of the target through the gap between said sputtering cathode and said cylindrical member and the gap between the target and said cathode shield.

5. The apparatus according to claim 4, wherein said first deposition shield is mounted on a surface of said cathode shield on the side of said first shutter plate.

6. The apparatus according to claim 1, wherein an edge of an opening in said first shutter plate is tapered.

7. A double rotary shutter unit, comprising:
a first shutter plate and a second shutter plate which are disposed to be independently rotatable while facing a sputtering cathode placed in a vacuum vessel and each of which includes at least one opening formed therein at a predetermined position, said second shutter plate being located at a position farther from said sputtering cathodes than said first shutter plate,
wherein a second deposition shield which surrounds the opening in said first shutter plate is mounted on a surface of said first shutter plate on a side of said second shutter plate.

8. A sputtering method performed by a sputtering apparatus which comprises a plurality of sputtering cathodes placed in a vacuum vessel, and a double rotary shutter mechanism including a first shutter plate and a second shutter plate which are disposed to be independently rotatable while facing the sputtering cathode and each of which includes at least one opening formed therein at a predetermined position, the second shutter plate being located at a position farther from the sputtering cathodes than the first shutter plate; in which a first deposition shield which laterally surrounds a front surface region of the sputtering cathode on a side of the first shutter plate is interposed between the sputtering cathode and the first shutter plate; and in which a second deposition shield which surrounds the opening in the first shutter plate is mounted on a surface of the first shutter plate on a side of the second shutter plate, the method comprising:
a pre-sputtering step of performing discharge while introducing a sputtering gas into the front surface region of the sputtering cathode on the side of the first shutter plate with an arrangement in which the opening in the first shutter plate is positioned in the front surface region and the opening in the second shutter plate is not positioned in the front surface region; and
a main sputtering step of performing discharge while introducing a sputtering gas into the front surface region of the sputtering cathode on the side of the first shutter plate with an arrangement in which both the opening in the first shutter plate and the opening in the second shutter plate are positioned in the front surface region.
